(19) United States
(12) Patent Application Publication
(10) Pub. No.: US 2026/0041297 A1
(43) Pub. Date: Feb. 12, 2026

(54) CLEANER CHARGING SYSTEM AND CHARGING STATION FOR CHARGING ROBOT CLEANER ACCORDING TO DOCKING STATE THEREWITH

(71) Applicant: Samsung Electronics Co., Ltd., Suwon-si (KR)

(72) Inventors: Wooram LEE, Suwon-si (KR); Kihoon KIM, Suwon-si (KR); Minji KIM, Suwon-si (KR); Jichul KIM, Suwon-si (KR); Hyeongjun KIM, Suwon-si (KR); Kyungjin OH, Suwon-si (KR)

(21) Appl. No.: 19/358,934

(22) Filed: Oct. 15, 2025

Related U.S. Application Data
(63) Continuation of application No. PCT/KR2024/006373, filed on May 10, 2024.

(30) Foreign Application Priority Data
Jul. 5, 2023 (KR) 10-2023-0087219

(51) Int. Cl. A47L 9/28; A47L 9/00; G01R 19/165; H02J 7/00

(52) U.S. Cl. CPC A47L 9/2873; A47L 9/0063; G01R 19/16576; H02J 7/0036; H02J 7/0044; A47L 2201/022

(57) ABSTRACT

A cleaner charging system is provided. The cleaner charging system includes a charging station and a robot cleaner. The robot cleaner receives power from the charging station and includes a motor, an impeller that is rotated by the motor and generates a suction force, a suction opening that is an inlet through which dust is suctioned by the suction force, a dust container in which the suctioned dust is collected, a third docking terminal, a fourth docking terminal, a battery, and a second switching device that connects the third docking terminal and the battery.

### CROSS-REFERENCE TO RELATED APPLICATION(S)

This application is a continuation application, claiming priority under 35 U.S.C. § 365(c), of an International application No. PCT/KR2024/006373, filed on May 10, 2024, which is based on and claims the benefit of a Korean patent application number 10-2023-0087219, filed on Jul. 5, 2023, in the Korean Intellectual Property Office, the disclosure of which is incorporated by reference herein in its entirety.

### BACKGROUND

### 1. Field

The disclosure relates to a cleaner charging system and a charging station. More particularly, the disclosure relates to a cleaner charging system that charges a subject for charging according to a docking state with the subject for charging, and a charging station.

### 2. Description of Related Art

As electronic technologies developed, electronic apparatuses providing various functions are being developed. In particular, recently, home appliances that perform charging automatically without a user's control are being distributed.

For example, if a robot cleaner (a main body) is docked with a charging station (a charger), the robot cleaner may be supplied with a specific amount of power from the charging station, and a microcontroller unit (MCU) of the robot cleaner may be turned on. The MCU may notify whether docking was performed by transmitting an infrared (IR) signal to the charging station, and when the IR signal is received, the charging station may supply power having a specific battery charging voltage to the robot cleaner.

For such an operation, the charging station needs to supply a specific amount of power, and there is a problem that standby power is consumed. Also, not considering a docking state between the charging station and the robot cleaner may also become a problem. For example, power loss due to an unaligned state, increase of a contact resistance due to moisture/dust, or the like, and increase of the temperature, or the like, may be generated.

Accordingly, a method for resolving the aforementioned problems needs to be developed.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a cleaner charging system that charges a subject for charging according to a docking state with the subject for charging, and a charging station.

Additional aspects will be set forth in part in the description which follows and, in part, will be apparent from the description, or may be learned by practice of the presented embodiments.

In accordance with an aspect of the disclosure, a cleaner charging system is provided. The cleaner charging system includes a charging station including a first docking terminal, a second docking terminal, a power supply device configured to generate first power having a first voltage and second power having a second voltage bigger than the first voltage, and a first switching device configured to supply the first power or the second power to the first docking terminal, and a robot cleaner that is supplied with power from the charging station, and includes a motor, an impeller that is rotated by the motor and generates a suction force, a suction opening that is an inlet through which dust is suctioned by the suction force, a dust container in which the suctioned dust is collected, a third docking terminal, a fourth docking terminal, a battery, and a second switching device configured to connect the third docking terminal and the battery, wherein the charging station is configured to control the first switching device such that the first power is supplied to the first docking terminal, based on identifying a flow of a current from the first docking terminal to the second docking terminal via the third docking terminal and the fourth docking terminal, identify that the robot cleaner was docked with the charging station, and control the first switching device such that the second power is supplied to the first docking terminal, and wherein the robot cleaner is configured to, based on identifying the flow of the current, charge the battery with the second power by turning on the second switching device.

Also, the first switching device includes a diode of which an anode is connected to a terminal outputting the second power at the power supply device, and of which a cathode is connected to the first docking terminal, and a first switch of which one end is connected to the terminal outputting the second power at the power supply device, and of which the other end is connected to the first docking terminal, and the charging station, based on identifying that the robot cleaner was docked with the charging station, turns on the first switch such that the second power is supplied to the first docking terminal.

In addition, the charging station detects a voltage of the second docking terminal, and based on identifying the flow of the current and the detected voltage being greater than or equal to a predetermined voltage, controls the first switching device such that the second power is supplied to the first docking terminal.

Also, the charging station further includes a docking detection device configured to be connected to the second docking terminal and identify the flow of the current, and the charging station identifies the flow of the current based on information provided by the docking detection device.

In addition, the charging station further includes a second switch of which one end is connected to the second docking terminal, and a resistance of which one end is connected to the other end of the second switch, and of which the other end is grounded, and the charging station, based on identifying that the robot cleaner was docked with the charging station, turns on the second switch, and the resistance has a smaller resistance value than a resistance of the docking detection device.

Further, the charging station identifies a current value of the flow of the current based on a voltage applied to the resistance, and based on the current value being changed by greater than or equal to a predetermined ratio, controls the first switching device and turns off the second switch such that the first power is supplied to the first docking terminal.

Also, the second switching device includes a third switch connecting the third docking terminal and the battery, and the robot cleaner, based on identifying the flow of the current, connects the third docking terminal and the battery by turning on the third switch, and based on charging of the battery being completed, releases the connection between the first docking terminal and the battery by turning off the third switch, and the charging station, based on the current value being changed by greater than or equal to the predetermined ratio as the connection between the third docking terminal and the battery is released, controls the first switching device and turns off the second switch such that the first power is supplied to the first docking terminal.

In addition, the charging station, based on the current value being changed by greater than or equal to the predetermined ratio as the robot cleaner contacts the charging station in a poor contact state based on at least one of change of a posture or movement of a location of the robot cleaner, controls the first switching device and turns off the second switch such that the first power is supplied to the first docking terminal.

Further, the docking detection device includes a first resistance of which one end is connected to the second docking terminal, a second resistance of which one end is connected to the other end of the first resistance, and of which the other end is grounded, and a transistor of which a base is connected to the other end of the first resistance, and of which an emitter is grounded, and the transistor is turned on based on the flow of the current, and the charging station identifies that the robot cleaner was docked with the charging station based on a voltage of a collector of the transistor.

Also, the charging station detects a voltage of the second docking terminal, and based on identifying the flow of the current and the detected voltage being smaller than a predetermined voltage, identifies that the robot cleaner contacted in a poor contact state, and provide information guiding poor contact to the robot cleaner or a user terminal.

In accordance with another aspect of the disclosure, a charging station configured to supply power to a robot cleaner is provided. The charging station includes a first docking terminal, a second docking terminal, a power supply device configured to generate first power having a first voltage and second power having a second voltage bigger than the first voltage, a first switching device configured to supply the first power or the second power to the first docking terminal, memory, including one or more storage media, storing instructions, and at least one processor communicatively coupled to the power supply device, the first switching device, and the memory, wherein the instructions, when executed by the at least one processor individually or collectively, cause the charging station to control the first switching device such that the first power is supplied to the first docking terminal, and based on identifying a flow of a current from the first docking terminal to the second docking terminal, identify that the robot cleaner was docked with the charging station, and control the first switching device such that the second power is supplied to the first docking terminal.

Also, the first switching device includes a diode of which an anode is connected to a terminal outputting the second power at the power supply device, and of which a cathode is connected to the first docking terminal, and a first switch of which one end is connected to the terminal outputting the second power at the power supply device, and of which the other end is connected to the first docking terminal, and the processor, based on identifying that the robot cleaner was docked with the charging station, turns on the first switch such that the second power is supplied to the first docking terminal.

In addition, the processor detects a voltage of the second docking terminal, and based on identifying the flow of the current and the detected voltage being greater than or equal to a predetermined voltage, controls the first switching device such that the second power is supplied to the first docking terminal.

Also, the charging station further includes a docking detection device configured to be connected to the second docking terminal and identifies the flow of the current, and the processor identifies the flow of the current based on information provided by the docking detection device.

In addition, the charging station further includes a second switch of which one end is connected to the second docking terminal, and a resistance of which one end is connected to the other end of the second switch, and of which the other end is grounded, and the processor, based on identifying that the robot cleaner was docked with the charging station, turns on the second switch, and the resistance has a smaller resistance value than a resistance of the docking detection device.

Further, the processor identifies a current value of the flow of the current based on a voltage applied to the resistance, and based on the current value being changed by greater than or equal to a predetermined ratio, controls the first switching device and turns off the second switch such that the first power is supplied to the first docking terminal.

Also, the robot cleaner, based on identifying the flow of the current, connects the first docking terminal and the battery by turning on a third switch connecting the first docking terminal and the battery of the robot cleaner, and based on charging of the battery being completed, releases the connection between the first docking terminal and the battery by turning off the third switch, and the processor, based on the current value being changed by greater than or equal to the predetermined ratio as the connection between the first docking terminal and the battery is released, controls the first switching device and turns off the second switch such that the first power is supplied to the first docking terminal.

In addition, the processor, based on the current value being changed by greater than or equal to the predetermined ratio as the robot cleaner contacts the charging station in a poor contact state based on at least one of change of a posture or movement of a location of the robot cleaner, controls the first switching device and turns off the second switch such that the first power is supplied to the first docking terminal.

Further, the docking detection device includes a first resistance of which one end is connected to the second docking terminal, a second resistance of which one end is connected to the other end of the first resistance, and of which the other end is grounded, and a transistor of which a base is connected to the other end of the first resistance, and of which an emitter is grounded, and the transistor is turned on based on the flow of the current, and the processor identifies that the robot cleaner was docked with the charging station based on a voltage of a collector of the transistor.

Also, the processor detects a voltage of the second docking terminal, and based on identifying the flow of the current and the detected voltage being smaller than a predetermined voltage, identifies that the robot cleaner contacted in a poor contact state, and provides information guiding poor contact to the robot cleaner or a user terminal.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram illustrating an Internet of things (IOT) environment according to an embodiment of the disclosure;

FIG. 2 is a block diagram illustrating a configuration of an electronic system according to an embodiment of the disclosure;

FIG. 3 is a block diagram illustrating a configuration of an electronic apparatus according to an embodiment of the disclosure;

FIG. 4 is a diagram illustrating circuitry configurations of an electronic apparatus and another electronic apparatus according to an embodiment of the disclosure;

FIGS. 5 and 6 are diagrams illustrating an operation of an electronic apparatus according to various embodiments of the disclosure;

FIG. 7 is a diagram illustrating an operation according to a docking state according to an embodiment of the disclosure;

FIG. 8 is a flowchart illustrating a charging operation according to an embodiment of the disclosure; and

FIG. 9 is a flowchart illustrating a control method of an electronic apparatus according to an embodiment of the disclosure.

Throughout the drawings, it should be noted that like reference numbers are used to depict the same or similar elements, features, and structures.

### DETAILED DESCRIPTION

The purpose of the disclosure is in providing a cleaner charging system for charging home appliances effectively while reducing power consumption, and a charging station.

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

Further, in the disclosure, each of the phrases, such as “A or B,” “at least one of A and B,” “at least one of A or B,” “A, B or C,” “at least one of A, B and C,” and “at least one of A, B, or C” may include any one of the items listed together with the phrase among the above phrases, or all possible combinations thereof.

Also, terms, such as “first,” “second,” and the like may be used just to distinguish a component from another component, and are not intended to limit a component in another aspect (e.g., importance or order).

Meanwhile, in case it is mentioned that a component (e.g., a first component) is “coupled” or “connected” with another component (e.g., a second component) together with terms, such as “functionally” and “communicatively” or without such terms, it means that the component may be connected with the another component directly (e.g., in a wired manner), wirelessly, or through a third component.

Also, terms, such as “include” or “have” should be construed as designating that there are such characteristics, numbers, steps, operations, elements, components, or a combination thereof described in the specification, but not as excluding in advance the existence or possibility of adding one or more of other characteristics, numbers, steps, operations, elements, components, or a combination thereof.

In addition, in case it is mentioned that one element is “connected with,” “combined with,” “supported by,” or “contacted with” another element not only includes a case wherein the elements are directly connected, combined, supported, or contacted, but also a case wherein the elements are indirectly connected, combined, supported, or contacted through a third element.

Further, the description in the disclosure that one element is “on top of” another element not only includes a case wherein the one element contacts the another element, but also a case wherein still another element exists between the two elements.

Also, the term “and/or” includes a combination of a plurality of related components described, or any one component among the plurality of related components described.

Hereinafter, the operating principle and embodiments of the disclosure will be described with reference to the accompanying drawings.

It should be appreciated that the blocks in each flowchart and combinations of the flowcharts may be performed by one or more computer programs which include computer-executable instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g., a central processing unit (CPU)), a communication processor (CP, e.g., a modem), a graphical processing unit (GPU), a neural processing unit (NPU) (e.g., an artificial intelligence (AI) chip), a wireless-fidelity (Wi-Fi) chip, a Bluetooth™ chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an IC, or the like.

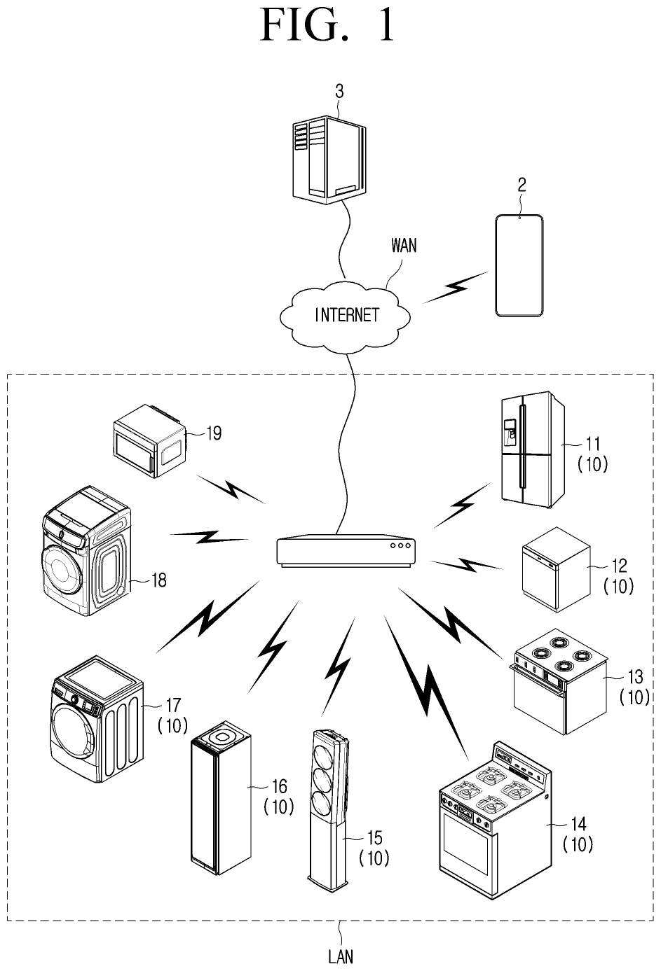

FIG. 1 is a diagram illustrating an IoT environment according to an embodiment of the disclosure.

Referring to FIG. 1, a home appliance 10 may include a communication module that can communicate with another home appliance, a user device 2, or a server 3, a user interface that receives a user input or outputs information to a user, at least one processor that controls the operations of the home appliance 10, and at least one memory storing a program for controlling the operations of the home appliance 10.

The home appliance 10 may be at least one of various types of home appliances. For example, the home appliance 10 may include at least one of a refrigerator 11, a dishwasher 12, an electric range 13, an electric oven 14, an air conditioner 15, a clothing management device 16, a washing machine 17, a dryer 18, or a microwave oven 19 as illustrated in the drawing, but is not limited thereto, and may include, for example, various types of home appliances, such as a robot cleaner, a vacuum cleaner, a television, or the like, not illustrated in the drawing. Also, the home appliances mentioned above are merely examples, and other than the home appliances mentioned above, a device that can be connected with another home appliance, the user device 2, or the server 3, and perform operations that will be described below may be included in the home appliance 10 according to an embodiment.

The server 3 may include a communication module that can communicate with another server, the home appliance 10, or the user device 2, and at least one processor that can process data received from another server, the home appliance 10, or the user device 2, and at least one memory that can store a program for processing data or processed data. Such a server 3 may be implemented as various computing devices, such as a workstation, a cloud, a data drive, a data station, or the like. The server 3 may be implemented as one or more servers that are physically or logically divided based on functions, detailed configurations of the functions, or data, or the like, and may transmit and receive data through communication between each server, and process the transmitted and received data.

The server 3 may perform functions, such as managing a user account, registering the home appliance 10 by associating it with the user account, and managing or controlling the registered home appliance 10, or the like. For example, the user may access the server 3 through the user device 2, and generate a user account. The user account may be identified by an identification (ID) and a password set by the user. The server 3 may register the home appliance 10 to the user account according to a designated procedure. For example, the server 3 may register, manage, and control the home appliance 10 by connecting identification information (e.g., a serial number or a medium access control (MAC) address, or the like) of the home appliance 10 to the user account. The user device 2 may include a communication module that can communicate with the home appliance 10 or the server 3, a user interface that receives a user input or outputs information to the user, at least one processor that controls the operations of the user device 2, and at least one memory storing a program for controlling the operations of the user device 2.

The user device 2 may be carried by the user, or arranged in the user's home or office, or the like. The user device 2 may include a personal computer, a terminal, a portable telephone, a smart phone, a handheld device, a wearable device, or the like, but is not limited thereto.

In the memory of the user device 2, a program for controlling the home appliance 10, i.e., an application may be stored. The application may be sold in a state of being installed in the user device 2, or may be downloaded from an external server and installed.

The user may access the server 3 by executing the application installed in the user device 2 and generate a user account, and perform communication with the server 3 based on the logged-on user account and register the home appliance 10.

For example, if the home appliance 10 is manipulated such that the home appliance 10 can access the server 3 according to a procedure guided by the application installed in the user device 2, the home appliance 10 may be registered to the user account by registering the identification information (e.g., the serial number or the MAC address, or the like) of the home appliance 10 in the user account at the server 3.

The user may control the home appliance 10 by using the application installed in the user device 2. For example, if the user logs on to the user account by the application installed in the user device 2, the home appliance 10 registered to the user account appears, and if the user inputs a control command for the home appliance 10, the control command may be transmitted to the home appliance 10 through the server 3.

A network may include both of a wired network and a wireless network. A wired network may include a cable network or a telephone network, or the like, and a wireless network may include all networks that transmit and receive signals through radio waves. A wired network and a wireless network may be connected with each other.

A network may include a wide area network (WAN), such as the Internet, or the like, and a local area network (LAN) formed with an access point (AP) as the center, and a wireless local area network not via an access point (AP). A wireless local area network may include Bluetooth™ (IEEE 802.15.1), Zigbee (IEEE 802.15.4), wireless fidelity (Wi-Fi) Direct, Near Field Communication (NFC), Z-Wave, or the like, but is not limited thereto.

The access point (AP) may connect the home appliance 10 or the user device 2 to the wide area network (WAN) to which the server 3 is connected. The home appliance 10 or the user device 2 may be connected to the server 3 through the wide area network (WAN).

The access point (AP) may communicate with the home appliance 10 or the user device 2 by using wireless communication, such as Wi-Fi™ (IEEE 802.11), Bluetooth™ (IEEE 802.15.1), Zigbee (IEEE 802.15.4), or the like, and access the wide area network (WAN) by using wired communication, but is not limited thereto.

According to various embodiments of the disclosure, the home appliance 10 may be directly connected with the user device 2 or the server 3 not via the access point (AP).

The home appliance 10 may be connected with the user device 2 or the server 3 via a wireless wide area network or a wireless local area network.

For example, the home appliance 10 may be connected with the user device 2 through a wireless local area network (e.g., Wi-Fi Direct).

As another example, the home appliance 10 may be connected with the user device 2 or the server 3 through a wide area network (WAN) by using a wireless wide area network (e.g., a cellular communication module).

As still another example, the home appliance 10 may access a wide area network (WAN) by using wired communication, and may be connected with the user device 2 or the server 3 through the wide area network (WAN).

In case the home appliance 10 can access the wide area network (WAN) by using wired communication, it may operate as an access point. Accordingly, the home appliance 10 may connect another home appliance to the wide area network (WAN) to which the server 3 is connected. Also, the another home appliance may connect the home appliance 10 to the wide area network (WAN) to which the server 3 is connected.

The home appliance 10 may transmit information on operations or states to the another home appliance, the user device 2, or the server 3 through the network. For example, the home appliance 10 may transmit information on operations or states to the another home appliance, the user device 2, or the server 3 in case a request is received from the server 3, or a specific event occurred in the home appliance 10, or periodically or in real time. When information on operations or states is received from the home appliance 10, the server 3 may update the information on operations or states of the home appliance 10 that was stored, and transmit the updated information on operations or states of the home appliance 10 to the user device 2 through the network. Here, update of the information may include various operations wherein the existing information is changed, such as an operation of adding new information to the existing information, an operation of replacing the existing information with new information, or the like.

The home appliance 10 may obtain various kinds of information from the another home appliance, the user device 2, or the server 3, and provide the obtained information to the user. For example, the home appliance 10 may obtain information, such as information related to functions of the home appliance 10 (e.g., a recipe, a washing method, or the like), and various environmental information (e.g., a weather, a temperature, humidity, or the like) from the server 3, and output the obtained information through the user interface.

The home appliance 10 may operate according to a control command received from the another home appliance, the user device 2, or the server 3. For example, even if there was no user input, in case the home appliance 10 obtained a pre-approval of the user so that it can operate according to a control command of the server 3, the home appliance 10 may operate according to a control command received from the server 3. Here, the control command received from the server 3 may include a control command that the user input through the user device 2 or a control command based on a predetermined condition, or the like, but is not limited thereto.

The user device 2 may transmit information on the user to the home appliance 10 or the server 3 through the communication module. For example, the user device 2 may transmit information on the user's location, the user's health state, the user's preference, the user's schedule, or the like, to the server 3. The user device 2 may transmit the information on the user to the server 3 according to a pre-approval of the user.

The home appliance 10, the user device 2, or the server 3 may determine a control command by using technologies, such as artificial intelligence, or the like. For example, the server 3 may receive information on operations or states of the home appliance 10 or receive information on the user of the user device 2, and process the information by using technologies, such as artificial intelligence, or the like, and transmit a processing result or a control command to the home appliance 10 or the user device 2 based on the processing result.

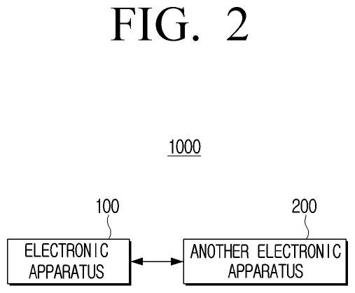

FIG. 2 is a block diagram illustrating a configuration of an electronic system 1000 according to an embodiment of the disclosure.

Referring to FIG. 2, the electronic system 1000 includes an electronic apparatus 100 and another electronic apparatus 200. For example, the electronic system 1000 may be a cleaner charging system, and may include a charging station as the electronic apparatus 100, and a robot cleaner as another electronic apparatus 200. However, the disclosure is not limited thereto, and any apparatus can be the electronic apparatus 100 if it is an apparatus that can charge the another electronic apparatus 200.

The electronic apparatus 100 may be an apparatus that charges the another electronic apparatus 200. For example, the electronic apparatus 100 may identify whether the another electronic apparatus 200 was docked with the electronic apparatus 100, and if it is identified that the another electronic apparatus 200 was docked with the electronic apparatus 100, the electronic apparatus 100 may supply power for charging the another electronic apparatus 200.

The another electronic apparatus 200 may be an apparatus that is docked with the electronic apparatus 100 and charged. For example, the another electronic apparatus 200 includes a circuitry configuration for the electronic apparatus 100 to detect whether docking was performed, and in case the electronic apparatus 100 supplies power for charging, the electronic apparatus 100 may perform a switching operation such that a current flowing in the circuitry configuration for detecting whether docking was performed flows in a battery inside the another electronic apparatus 200.

The electronic apparatus 100 may include a first docking terminal, a second docking terminal, a power supply device that generates first power having a first voltage and second power having a second voltage bigger than the first voltage, and a first switching device that supplies the first power or the second power to the first docking terminal, and the another electronic apparatus 200 may include a third docking terminal, a fourth docking terminal, a battery, and a second switching device that connects the third docking terminal and the battery. Also, the another electronic apparatus 200 may be supplied with power from the electronic apparatus 100, and further include a motor, an impeller that is rotated by the motor and generates a suction force, a suction opening that is an inlet through which dust is suctioned by the suction force, and a dust container in which the suctioned dust is collected. Here, the impeller may be a fan.

The electronic apparatus 100 may control the first switching device such that the first power is supplied to the first docking terminal, and if a flow of a current from the first docking terminal to the second docking terminal via the third docking terminal and the fourth docking terminal is identified, identify that the another electronic apparatus 200 was docked with the electronic apparatus 100, and control the first switching device such that the second power is supplied to the first docking terminal. Also, the another electronic apparatus 200 may, when the flow of the current is identified, charge the battery with the second power by turning on the second switching device.

The first switching device may include a diode of which an anode is connected to a terminal outputting the second power at the power supply device, and of which a cathode is connected to the first docking terminal, and a first switch of which one end is connected to the terminal outputting the second power at the power supply device, and of which the other end is connected to the first docking terminal, and the electronic apparatus 100 may, if it is identified that the another electronic apparatus 200 was docked with the electronic apparatus 100, turn on the first switch such that the second power is supplied to the first docking terminal.

The electronic apparatus 100 may detect a voltage of the second docking terminal, and when the flow of the current is identified and the detected voltage is greater than or equal to a predetermined voltage, the electronic apparatus 100 may control the first switching device such that the second power is supplied to the first docking terminal.

The electronic apparatus 100 may further include a docking detection device that is connected to the second docking terminal and identifies the flow of the current, and the electronic apparatus 100 may identify the flow of the current based on information provided by the docking detection device.

The electronic apparatus 100 may further include a second switch of which one end is connected to the second docking terminal, and a resistance of which one end is connected to the other end of the second switch, and of which the other end is grounded, and the electronic apparatus 100 may, if it is identified that the another electronic apparatus 200 was docked with the electronic apparatus 100, turn on the second switch. Here, the resistance may have a smaller resistance value than a resistance of the docking detection device.

The electronic apparatus 100 may identify a current value of the flow of the current based on a voltage applied to the resistance, and if the current value is changed by greater than or equal to a predetermined ratio, the electronic apparatus 100 may control the first switching device and turn off the second switch such that the first power is supplied to the first docking terminal.

The second switching device may include a third switch connecting the third docking terminal and the battery, and the another electronic apparatus 200 may, if the flow of the current is identified, connect the third docking terminal and the battery by turning on the third switch, and when charging of the battery is completed, release the connection between the first docking terminal and the battery by turning off the third switch. Also, the electronic apparatus 100 may, if the current value is changed by greater than or equal to the predetermined ratio as the connection between the third docking terminal and the battery is released, control the first switching device and turn off the second switch such that the first power is supplied to the first docking terminal.

If the current value is changed by greater than or equal to the predetermined ratio as the another electronic apparatus 200 contacts the electronic apparatus 100 in a poor contact state based on at least one of change of a posture or movement of a location of the another electronic apparatus 200, the electronic apparatus 100 may control the first switching device and turn off the second switch such that the first power is supplied to the first docking terminal.

The docking detection device may include a first resistance of which one end is connected to the second docking terminal, a second resistance of which one end is connected to the other end of the first resistance, and of which the other end is grounded, and a transistor of which a base is connected to the other end of the first resistance, and of which an emitter is grounded, and the transistor may be turned on based on the flow of the current, and the electronic apparatus 100 may identify that the another electronic apparatus 200 was docked with the electronic apparatus 100 based on a voltage of a collector of the transistor.

The electronic apparatus 100 may detect a voltage of the second docking terminal, and if the flow of the current is identified and the detected voltage is smaller than a predetermined voltage, the electronic apparatus 100 may identify that the another electronic apparatus 200 contacted in a poor contact state, and provide information guiding poor contact to the another electronic apparatus 200 or a user terminal.

Meanwhile, the another electronic apparatus 200 may further include a driver, and the location of the another electronic apparatus 200 may be changed by controlling the driver of the another electronic apparatus 200. Also, in case the another electronic apparatus 200 was implemented as a robot cleaner, it may include at least one of a component for absorbing dust or a wet mop.

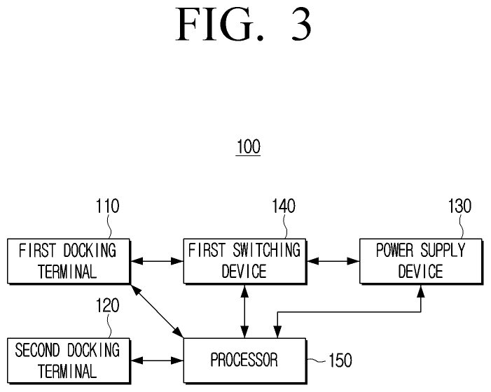

FIG. 3 is a block diagram illustrating a configuration of an electronic apparatus according to an embodiment of the disclosure.

Referring to FIG. 3, the electronic apparatus 100 includes a first docking terminal 110, a second docking terminal 120, a power supply device 130, a first switching device 140, and a processor 150.

The first docking terminal 110 and the second docking terminal 120 may be terminals for which docking of the another electronic apparatus 200 is performed. For example, the first docking terminal 110 and the second docking terminal 120 may respectively be connected to the third docking terminal and the fourth docking terminal of the another electronic apparatus 200.

The first docking terminal 110 and the second docking terminal 120 may be terminals to which the another electronic apparatus 200 is docked, and may be terminals for supplying power to the another electronic apparatus 200.

The power supply device 130 may generate first power having a first voltage and second power having a second voltage bigger than the first voltage. For example, the power supply device 130 may generate the first power having 3.3V and the second power having 17.54V. However, the disclosure is not limited thereto, and the power supply device 130 may generate power having voltages of any different sizes.

Here, the first power and the second power may be power for driving the electronic apparatus 100. In other words, the power supply device 130 may generate the first power and the second power for driving the electronic apparatus 100, and charge the another electronic apparatus 200 by using the first power and the second power.

The first switching device 140 may supply the first power and the second power to the first docking terminal 110. For example, the first switching device 140 may be arranged between the first docking terminal 110 and the power supply device 130, and supply one of the first power or the second power generated by the power supply device 130 to the first docking terminal 110.

The first switching device 140 may include a component that actively performs a switching operation. For example, the first switching device 140 may include a transistor, and actively perform a switching operation based on a voltage applied to a gate of the transistor. Alternatively, the first switching device 140 may include a component that passively performs a switching operation. For example, the first switching device 140 may include a diode, and passively perform a switching operation based on a voltage applied to both ends of the diode.

The processor 150 controls the overall operations of the electronic apparatus 100. Specifically, the processor 150 may be connected with each component of the electronic apparatus 100, and control the overall operations of the electronic apparatus 100. For example, the processor 150 may be connected with components, such as the first docking terminal 110, the second docking terminal 120, the power supply device 130, the first switching device 140, or the like, and control the operations of the electronic apparatus 100.

The at least one processor 150 may include one or more of a CPU, a graphics processing unit (GPU), an accelerated processing unit (APU), a many integrated core (MIC), a neural processing unit (NPU), a hardware accelerator, or a machine learning accelerator. The at least one processor 150 may control one or a random combination of the other components of the electronic apparatus 100, and perform an operation related to communication or data processing. Also, the at least one processor 150 may execute one or more programs or instructions stored in the memory. For example, the at least one processor 150 may perform the method according to an embodiment of the disclosure by executing the one or more instructions stored in the memory.

In case the method according to an embodiment of the disclosure includes a plurality of operations, the plurality of operations may be performed by one processor, or performed by a plurality of processors. For example, when a first operation, a second operation, and a third operation are performed by the method according to an embodiment of the disclosure, all of the first operation, the second operation, and the third operation may be performed by a first processor, or the first operation and the second operation may be performed by the first processor (e.g., a generic-purpose processor), and the third operation may be performed by a second processor (e.g., an artificial intelligence-dedicated processor).

The at least one processor 150 may be implemented as a single core processor including one core, or it may be implemented as one or more multicore processors including a plurality of cores (e.g., multicores of the same kind or multicores of different kinds). In case the at least one processor 150 is implemented as multicore processors, each of the plurality of cores included in the multicore processors may include internal memory of the processor, such as cache memory, on-chip memory, or the like, and a common cache shared by the plurality of cores may be included in the multicore processors. Also, each of the plurality of cores (or some of the plurality of cores) included in the multicore processors may independently read a program instruction for implementing the method according to an embodiment of the disclosure and perform the instruction, or the plurality of entire cores (or some of the cores) may be linked with one another, and read a program instruction for implementing the method according to an embodiment of the disclosure and perform the instruction.

In case the method according to an embodiment of the disclosure includes a plurality of operations, the plurality of operations may be performed by one core among the plurality of cores included in the multicore processors, or they may be performed by the plurality of cores. For example, when the first operation, the second operation, and the third operation are performed by the method according to an embodiment of the disclosure, all of the first operation, the second operation, and the third operation may be performed by a first core included in the multicore processors, or the first operation and the second operation may be performed by the first core included in the multicore processors, and the third operation may be performed by a second core included in the multicore processors.

In the embodiments of the disclosure, the at least one processor 150 may mean a system on chip (SoC) wherein at least one processor and other electronic components are integrated, a single core processor, a multicore processor, or a core included in the single core processor or the multicore processor. Also, here, the core may be implemented as a CPU, a GPU, an APU, a MIC, an NPU, a hardware accelerator, or a machine learning accelerator, or the like, but the embodiments of the disclosure are not limited thereto. Meanwhile, hereinafter, the operations of the electronic apparatus 100 will be explained with the expression ‘the processor 150,’ for the convenience of explanation.

The processor 150 may control the first switching device 140 such that the first power is supplied to the first docking terminal 110, and if a flow of a current from the first docking terminal 110 to the second docking terminal 120 is identified, the processor 150 may identify that the another electronic apparatus 200 was docked with the electronic apparatus 100, and control the first switching device 140 such that the second power is supplied to the first docking terminal 110.

For example, in a state wherein it was identified that the another electronic apparatus 200 was not docked with the electronic apparatus 100, the processor 150 may control the first switching device 140 such that the first power is supplied to the first docking terminal 110. Afterwards, if the another electronic apparatus 200 is docked with the electronic apparatus 100, the processor 150 may identify a flow of a current from the first docking terminal 110 to the second docking terminal 120. For example, if the first docking terminal 110 and the second docking terminal 120 are respectively connected with the third docking terminal and the fourth docking terminal of the another electronic apparatus 200, a current path is formed, and the processor 150 can identify a flow of a current from the first docking terminal 110 to the second docking terminal 120. Here, the flow of the current from the first docking terminal 110 to the second docking terminal 120 may be a current that flows from the first docking terminal 110 to the second docking terminal 120 via the third docking terminal and the fourth docking terminal. If it is identified that the another electronic apparatus 200 was docked with the electronic apparatus 100, the processor 150 may control the first switching device 140 such that the second power is supplied to the first docking terminal 110.

The first switching device 140 may include a diode of which an anode is connected to a terminal outputting the second power at the power supply device 130, and of which a cathode is connected to the first docking terminal 110, and a first switch of which one end is connected to the terminal outputting the second power at the power supply device 130, and of which the other end is connected to the first docking terminal 110. Also, if it is identified that the another electronic apparatus 200 was docked with the electronic apparatus 100, the processor 150 may turn on the first switch such that the second power is supplied to the first docking terminal 110. Here, the diode may be naturally turned off as the second power is supplied to the first docking terminal 110.

However, the disclosure is not limited thereto, and the first switching device 140 may include a first switch of which one end is connected to the terminal outputting the second power at the power supply device 130, and of which the other end is connected to the first docking terminal 110, and an additional switch of which one end is connected to the terminal outputting the second power at the power supply device 130, and of which the other end is connected to the first docking terminal 110. In this case, if it is identified that the another electronic apparatus 200 was docked with the electronic apparatus 100, the processor 150 may turn on the first switch, and turn off the additional switch such that the second power is supplied to the first docking terminal 110.

The processor 150 may detect a voltage of the second docking terminal 120, and if the flow of the current is identified and the detected voltage is greater than or equal to a predetermined voltage, the processor 150 may control the first switching device 140 such that the second power is supplied to the first docking terminal 110. In this case, even if the flow of the current was identified, if the voltage of the second docking terminal 120 is smaller than the predetermined voltage, the processor 150 may not perform any operation. Accordingly, the state wherein the first power is supplied may be maintained at the first docking terminal 110.

The electronic apparatus 100 may further include a docking detection device that is connected to the second docking terminal 120 and identifies the flow of the current, and the processor 150 may identify the flow of the current based on information provided by the docking detection device.

For example, the docking detection device may include a first resistance of which one end is connected to the second docking terminal, a second resistance of which one end is connected to the other end of the first resistance, and of which the other end is grounded, and a transistor of which a base is connected to the other end of the first resistance, and of which an emitter is grounded, and the transistor may be turned on based on the flow of the current, and the processor 150 may identify that the another electronic apparatus 200 was docked with the electronic apparatus 100 based on a voltage of a collector of the transistor.

The electronic apparatus 100 may further include a second switch of which one end is connected to the second docking terminal, and a resistance of which one end is connected to the other end of the second switch, and of which the other end is grounded, and if it is identified that the another electronic apparatus 200 was docked with the electronic apparatus 100, the processor 150 may turn on the second switch. Here, the resistance may have a smaller resistance value than a resistance of the docking detection device. Accordingly, while charging is performed, power consumption can be reduced by reducing the current flowing to the docking detection device.

The processor 150 may identify a current value of the flow of the current based on a voltage applied to the resistance, and if the current value is changed by greater than or equal to a predetermined ratio, the processor 150 may control the first switching device 140 and turn off the second switch such that the first power is supplied to the first docking terminal 110. For example, if the current value is changed by greater than or equal to the predetermined ratio as the another electronic apparatus 200 contacts the electronic apparatus 100 in a poor contact state based on at least one of change of a posture or movement of a location of the another electronic apparatus 200, the processor 150 may control the first switching device 140 and turn off the second switch such that the first power is supplied to the first docking terminal 110, and may thereby change the operation state of the electronic apparatus 100 to the state before charging was performed.

If the flow of the current is identified, the another electronic apparatus 200 may connect the first docking terminal 110 and the battery by turning on the third switch that connects the first docking terminal 110 and the battery of the another electronic apparatus 200, and when charging of the battery is completed, the another electronic apparatus 200 may release the connection between the first docking terminal 110 and the battery by turning off the third switch. Also, if the current value is changed by greater than or equal to the predetermined ratio as the connection between the first docking terminal 110 and the battery is released, the processor 150 may control the first switching device 140 and turn off the second switch such that the first power is supplied to the first docking terminal 110. In other words, the processor 150 may change the operation state of the electronic apparatus 100 to the state before charging was performed.

After the current value was changed, if the current value is changed again to the current value before it was changed, the processor 150 may restart charging by controlling the first switching device 140 such that the second power is supplied to the first docking terminal 110.

The electronic apparatus 100 may further include a communication interface, and the processor 150 may detect a voltage of the second docking terminal 120, and if the flow of the current is identified and the detected voltage is smaller than a predetermined voltage, the processor 150 may identify that the another electronic apparatus 200 contacted in a poor contact state, and control the communication interface to provide information guiding poor contact to the another electronic apparatus 200 or a user terminal.

Here, the communication interface is a component performing communication with various types of external devices according to various types of communication methods. For example, the electronic apparatus 100 may perform communication with the another electronic apparatus 200 or a user terminal through the communication interface.

The communication interface may include a Wi-Fi module, a Bluetooth module, an infrared communication module, and a wireless communication module, or the like. Here, each communication module may be implemented in a form of at least one hardware chip.

A Wi-Fi module and a Bluetooth module perform communication by a Wi-Fi method and a Bluetooth method, respectively. In the case of using a Wi-Fi module or a Bluetooth module, various types of connection information, such as a service set identifier (SSID) and a session key is transmitted and received first, and connection of communication is performed by using the information, and various types of information can be transmitted and received thereafter. An infrared communication module performs communication according to an infrared data association (IrDA) technology of transmitting data to a near field wirelessly by using infrared rays between visible rays and millimeter waves.

A wireless communication module may include at least one communication chip that performs communication according to various wireless communication protocols, such as Zigbee, 3^{rd} generation (3G), 3^{rd} generation partnership project (3GPP), long term evolution (LTE), LTE advanced (LTE-A), 4^{th} generation (4G), 5^{th} generation (5G), or the like, other than the aforementioned communication methods.

Alternatively, the communication interface may include a wired communication interface, such as a high definition multimedia interface (HDMI), a displayport (DP), a thunderbolt, a USB, a red green blue (RGB), a D-subminiature (D-SUB), a digital visual interface (DVI), or the like.

Other than the above, the communication interface may include at least one of a local area network (LAN) module, an Ethernet module, or a wired communication module that performs communication by using a pair cable, a coaxial cable, or an optical fiber cable, or the like.

As described above, the electronic apparatus 100 can charge the another electronic apparatus 200 in consideration of not only whether the another electronic apparatus 200 was docked, but also the docking state of the another electronic apparatus 200, and thus the electronic apparatus 100 can charge the another electronic apparatus 200 more effectively while reducing power consumption.

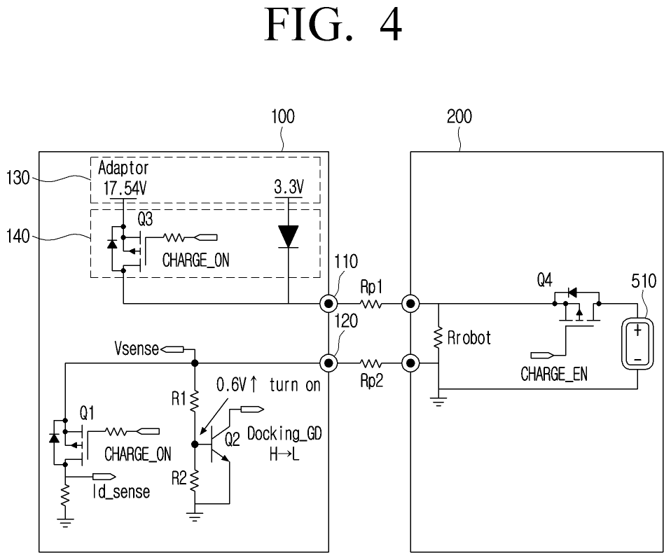

Hereinafter, operations of the electronic apparatus 100 will be described through FIGS. 4 to 8. In FIGS. 4 to 8, individual embodiments will be explained for the convenience of explanation. However, the individual embodiments in FIGS. 4 to 8 may be carried out in any combined states.

FIG. 4 is a diagram illustrating circuitry configurations of an electronic apparatus and another electronic apparatus according to an embodiment of the disclosure.

Referring to FIG. 4, the electronic apparatus 100 may include a first docking terminal 110, a second docking terminal 120, a power supply device 130, and a first switching device 140. The electronic apparatus 100 further includes a processor 150, but it was not illustrated in FIG. 4.

The electronic apparatus 100 may further include a second switch Q1 of which one end is connected to the second docking terminal 120, and a resistance of which one end is connected to the other end of the second switch Q1, and of which the other end is grounded.

The electronic apparatus 100 may further include a docking detection device connected to the second docking terminal 120, and the docking detection device may include a first resistance R1 of which one end is connected to the second docking terminal 120, a second resistance R2 of which one end is connected to the other end of the first resistance R1, and of which the other end is grounded, and a transistor Q2 of which a base is connected to the other end of the first resistance R1, and of which an emitter is grounded. Here, the equivalent resistance of the entire docking detection device may have a bigger resistance value than the resistance connected to the other end of the second switch Q1.

The first switching device 140 may include a diode of which an anode is connected to a terminal outputting the second power at the power supply device 130, and of which a cathode is connected to the first docking terminal 110, and a first switch Q3 of which one end is connected to the terminal outputting the second power at the power supply device 130, and of which the other end is connected to the first docking terminal 110.

The another electronic apparatus 200 may include a third docking terminal and a fourth docking terminal, and an Rpl resistance may exist between the first docking terminal 110 and the third docking terminal, and an Rp2 resistance may exist between the second docking terminal 120 and the fourth docking terminal.

The another electronic apparatus 200 may include an Rrobot resistance between the third docking terminal and the fourth docking terminal. The another electronic apparatus 200 may further include a battery 510, and a third switch Q4 of which one end is connected to the third docking terminal, and of which the other end is connected to one end of the battery 510, and the other end of the battery 510 may be connected to the fourth docking terminal.

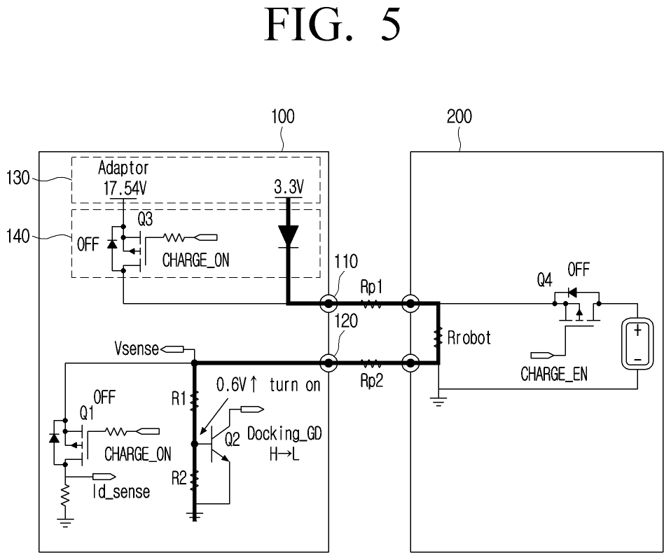

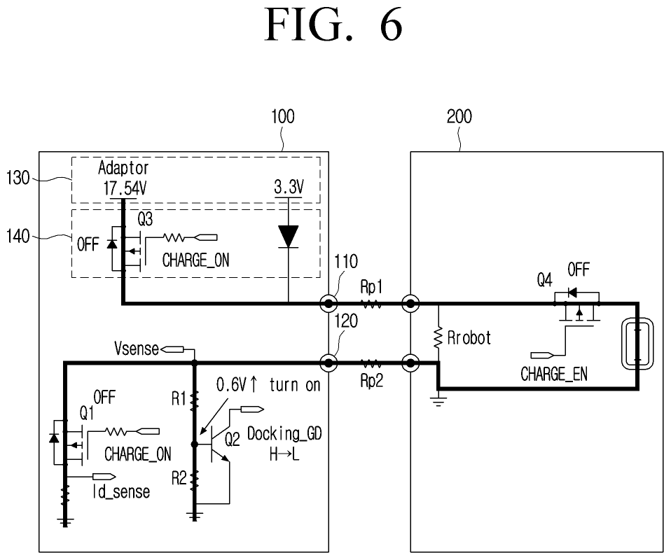

FIGS. 5 and 6 are diagrams illustrating an operation of an electronic apparatus according to various embodiments of the disclosure.

Referring to FIGS. 5 and 6, the processor 150 may control the first switching device 140 such that the first power is supplied to the first docking terminal 110. Afterwards, when the another electronic apparatus 200 is docked with the electronic apparatus 100, as in the bold line in FIG. 5, a current may flow from the first power through the Rpl resistance, the Rrobot resistance, the Rp2 resistance, and the docking detection device. In this case, the voltage applied to the second resistance R2 of the docking detection device may be Vcc×R2/(Rp1+Rrobot+Rp2+R1+R2).

If the voltage applied to the second resistance R2 is of a degree that can turn on the transistor Q2, the collector of the transistor Q2 may have a low value, and if the collector of the transistor Q2 is changed from a high value to a low value, the processor 150 may identify that the another electronic apparatus 200 was docked with the electronic apparatus 100.

If it is identified that the another electronic apparatus 200 was docked with the electronic apparatus 100, the processor 150 may turn on the first switch Q3 and the second switch Q1 through two CHARGE_ON terminals. In this case, the second power may be applied to the first docking terminal 110, and the diode within the first switching device 140 may be turned off. Also, as the second switch Q1 is turned on, a current gets to flow through the second switch Q1, and as the resistance connected to the other end of the second switch Q1 is smaller than the equivalent resistance of the docking detection device, most of the current may flow through the resistance connected to the other end of the second switch Q1. In other words, power consumed at the docking detection device can be reduced.

The processor included in the another electronic apparatus 200 may detect the voltage of the Rrobot resistance, and in case the voltage of the Rrobot resistance increases as the current flows as in FIG. 5, the third switch Q4 may be turned on through a CHARGE_EN, and the battery may be charged by controlling such that the current flows through the battery.

The current that flows during charging according to the operations of the electronic apparatus 100 and the another electronic apparatus 200 as above was illustrated by the bold line in FIG. 6.

Meanwhile, the processor 150 may detect a voltage of the Vsense node, and only when the voltage of the Vsense node is greater than or equal to a predetermined voltage, and a flow of a current was identified, the processor 150 may control the first switching device 140 such that the second power is supplied to the first docking terminal 110. If the another electronic apparatus 200 contacts the electronic apparatus 100 in a poor contact state, the resistance values of the Rpl resistance and the Rp2 resistance may become bigger, and the voltage of the Vsense node may become smaller. In other words, the processor 150 may not proceed with charging in the case of a poor contact state through the voltage of the Vsense node.

The processor 150 may detect a current ID_sense that flows through the node based on the voltage of the resistance connected to the other end of the second switch Q1. If the detected current is changed by greater than or equal to a predetermined ratio, the processor 150 may control the first switching device 140 and turn off the second switch Q1 such that the first power is supplied to the first docking terminal 110. In other words, the processor 150 may detect a case wherein it became a poor contact state during charging, and stop the charging.

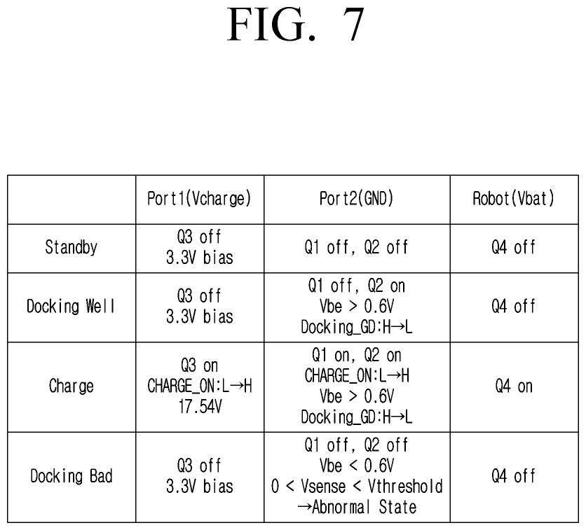

FIG. 7 is a diagram illustrating an operation according to a docking state according to an embodiment of the disclosure.

Referring to FIG. 7, first, a standby state may be before the another electronic apparatus 200 is docked with the electronic apparatus 100. In this case, all of the second switch Q1, the transistor Q2, the first switch Q3, and the third switch Q4 are in a turned-off state, and the first docking terminal (port 1) 110 may be in a state wherein the first power (3.3V) was applied. However, the disclosure is not limited thereto, and the voltage of the first power may be any different values.

When the another electronic apparatus 200 is docked with the electronic apparatus 100 (docking well), the voltage applied to the second resistance R2 exceeds 0.6V and the transistor Q2 is turned on, and the collector of the transistor Q2 may be changed from a high value to a low value.

The processor 150 may turn on the second switch Q1 and the first switch Q3 by detecting a low value of the collector of the transistor Q2, and the processor of the another electronic apparatus 200 may also turn on the third switch Q4 based on the voltage of the Rrobot resistance. In this case, the second power (17.54V) is applied to the first docking terminal 110, and the another electronic apparatus 200 may be charged. However, the disclosure is not limited thereto, and the voltage of the second power may be any different values.

If it becomes a poor contact state (docking bad) during charging, the voltage of the Vsense node may be changed to smaller than a predetermined voltage (Vthreshold). The charging may be stopped as the processor 150 turns off the second switch Q1 and the first switch Q3, and the processor of the another electronic apparatus 200 also turns off the third switch Q4 based on the voltage of the Rrobot resistance.

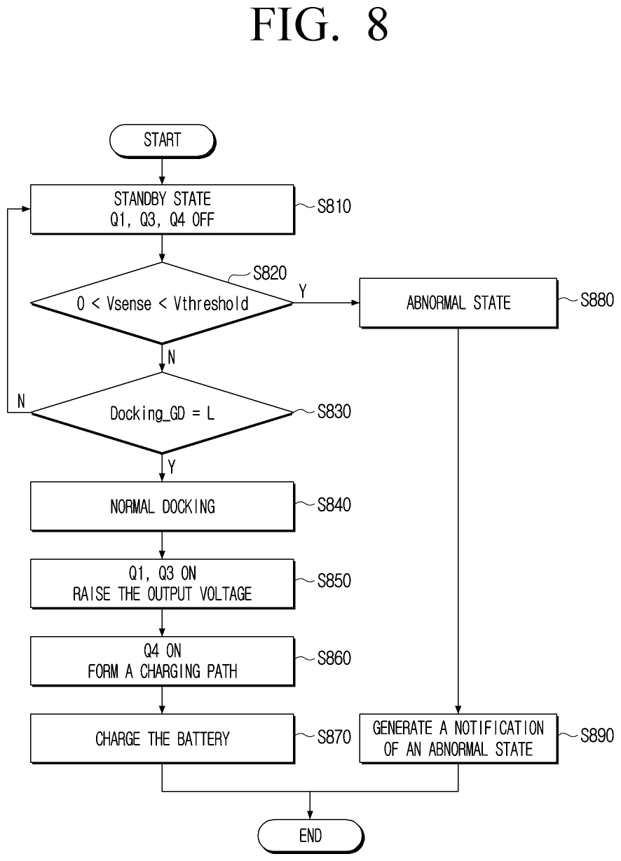

FIG. 8 is a flowchart for illustrating a charging operation according to an embodiment of the disclosure.

Referring to FIG. 8, first, all of the second switch Q1, the first switch Q3, and the third switch Q4 may be in a turned-off state in the operation S810. Afterwards, the processor 150 may identify whether the voltage of the Vsense node is smaller than the predetermined voltage (Vthreshold) in the operation S820, and if the voltage of the Vsense node is smaller than the predetermined voltage (Vthreshold), the processor 150 may identify that it is an abnormal state in the operation S880, and provide a notification of an abnormal state in the operation S890.

If the voltage of the Vsense node is greater than or equal to the predetermined voltage (Vthreshold), the processor 150 may identify whether the collector of the transistor Q2 has a low value in the operation S830, and if the collector of the transistor Q2 has a low value, the processor 150 may identify that docking was performed normally in the operation S840, and if the collector of the transistor Q2 does not have a low value, the processor 150 may maintain the standby state.

If it is identified that docking was performed normally, the processor 150 may raise the output voltage by turning on the second switch Q1 and the first switch Q3 in the operation S850, and the processor of the another electronic apparatus 200 may form a charging path by turning on the third switch Q4 based on the voltage of the Rrobot resistance in the operation S860. When the charging path is formed, the battery of the another electronic apparatus 200 may be charged in the operation S870.

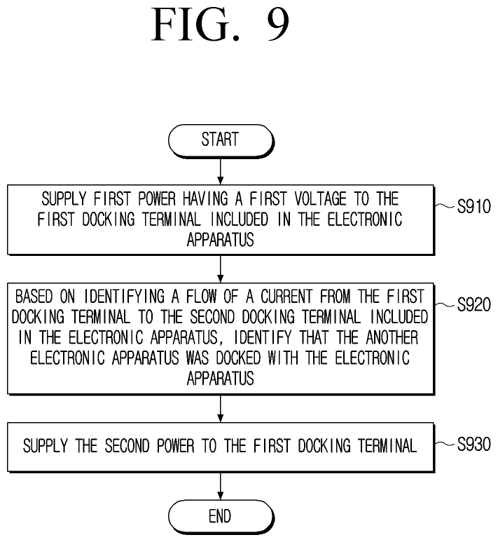

FIG. 9 is a flowchart for illustrating a control method of an electronic apparatus according to an embodiment of the disclosure.

Referring to FIG. 9, first, the first power having the first voltage is supplied to the first docking terminal included in the electronic apparatus in the operation S910. Then, if a flow of a current from the first docking terminal to the second docking terminal included in the electronic apparatus is identified, it is identified that the another electronic apparatus was docked with the electronic apparatus in the operation S920. Then, the second power is supplied to the first docking terminal in the operation S930.

Also, the control method may further include the operation of detecting a voltage of the second docking terminal, and in the operation S930 of supplying the second power, if the flow of the current is identified and the detected voltage is greater than or equal to a predetermined voltage, the second power may be supplied to the first docking terminal.

In addition, the control method may further include the operations of detecting a voltage of the second docking terminal, and if the flow of the current is identified and the detected voltage is smaller than the predetermined voltage, identifying that the another electronic apparatus contacted in a poor contact state, and providing information guiding poor contact to the another electronic apparatus or a user terminal.

According to the aforementioned various embodiments of the disclosure, the electronic apparatus can charge the another electronic apparatus in consideration of not only whether the another electronic apparatus was docked, but also the docking state of the another electronic apparatus, and thus the electronic apparatus can charge the another electronic apparatus more effectively while reducing power consumption.

Meanwhile, according to an embodiment of the disclosure, the aforementioned various embodiments may be implemented as software including instructions stored in machine-readable storage media, which can be read by machines (e.g., computers). The machines refer to devices that call instructions stored in a storage medium, and can operate according to the called instructions, and the devices may include an electronic apparatus according to the aforementioned embodiments (e.g., an electronic apparatus A). In case an instruction is executed by a processor, the processor may perform a function corresponding to the instruction by itself, or by using other components under its control. An instruction may include a code that is generated or executed by a compiler or an interpreter. A storage medium that is readable by machines may be provided in the form of a non-transitory storage medium. Here, the term ‘non-transitory’ only means that a storage medium does not include signals, and is tangible, but does not indicate whether data is stored in the storage medium semi-permanently or temporarily.

Also, according to an embodiment of the disclosure, a method according to the aforementioned various embodiments may be provided while being included in a computer program product. A computer program product refers to a product, and it can be traded between a seller and a buyer. A computer program product can be distributed in the form of a storage medium that is readable by machines (e.g., compact disc read only memory (CD-ROM)), or distributed on-line through an application store (e.g., PlayStore™). In the case of on-line distribution, at least a portion of a computer program product may be stored in a storage medium, such as the server of the manufacturer, the server of the application store, and the memory of the relay server at least temporarily, or may be generated temporarily.

In addition, according to an embodiment of the disclosure, the aforementioned various embodiments may be implemented in a recording medium that can be read by a computer or a device similar to a computer by using software, hardware or a combination thereof. In some cases, the embodiments described in this specification may be implemented as the processor itself. According to implementation by software, the embodiments of the disclosure, such as procedures and functions described in this specification may be implemented as separate software modules. Each of the software modules may perform one or more functions and operations described in this specification.

Meanwhile, computer instructions for performing processing operations of a device according to the aforementioned various embodiments may be stored in a non-transitory computer-readable medium. Computer instructions stored in such a non-transitory computer-readable-medium make the processing operations at a device according to the aforementioned various embodiments performed by a specific machine, when the instructions are executed by the processor of the specific machine. A non-transitory computer-readable medium refers to a medium that stores data semi-permanently, and is readable by machines, but not a medium that stores data for a short moment, such as register, cache, and memory. As specific examples of a non-transitory computer-readable medium, there may be a CD, a digital versatile disc (DVD), a hard disc, a blue-ray disc, a USB, memory card, ROM, and the like.

Also, each of the components (e.g., a module or a program) according to the aforementioned various embodiments may consist of a singular object or a plurality of objects. In addition, among the aforementioned corresponding sub components, some sub components may be omitted, or other sub components may be further included in the various embodiments. Alternatively or additionally, some components (e.g., a module or a program) may be integrated as an object, and perform functions that were performed by each of the components before integration identically or in a similar manner. Further, operations performed by a module, a program, or other components according to the various embodiments may be executed sequentially, in parallel, repetitively, or heuristically. Or, at least some of the operations may be executed in a different order or omitted, or other operations may be added.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device, cause the electronic device to perform a method of the disclosure.

Any such software may be stored in the form of volatile or non-volatile storage, such as, for example, a storage device like read only memory (ROM), whether erasable or rewritable or not, or in the form of memory, such as, for example, random access memory (RAM), memory chips, device or integrated circuits or on an optically or magnetically readable medium, such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method of any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A cleaner charging system comprising:
a charging station comprising a first docking terminal, a second docking terminal, a power supply device configured to generate first power having a first voltage and second power having a second voltage bigger than the first voltage, and a first switching device configured to supply the first power or the second power to the first docking terminal; and
a robot cleaner that is supplied with power from the charging station, and comprises a motor, an impeller that is rotated by the motor and generates a suction force, a suction opening that is an inlet through which dust is suctioned by the suction force, a dust container in which the suctioned dust is collected, a third docking terminal, a fourth docking terminal, a battery, and a second switching device configured to connect the third docking terminal and the battery,
wherein the charging station is configured to:
control the first switching device such that the first power is supplied to the first docking terminal,
based on identifying a flow of a current from the first docking terminal to the second docking terminal via the third docking terminal and the fourth docking terminal, identify that the robot cleaner was docked with the charging station, and
control the first switching device such that the second power is supplied to the first docking terminal, and
wherein the robot cleaner is configured to:
based on identifying the flow of the current, charge the battery with the second power by turning on the second switching device.

2. The cleaner charging system of claim 1,
wherein the first switching device comprises:
a diode of which an anode is connected to a terminal outputting the second power at the power supply device, and of which a cathode is connected to the first docking terminal, and
a first switch of which one end is connected to the terminal outputting the second power at the power supply device, and of which the other end is connected to the first docking terminal, and
wherein the charging station is configured to:
based on identifying that the robot cleaner was docked with the charging station, turn on the first switch such that the second power is supplied to the first docking terminal.

3. The cleaner charging system of claim 1, wherein the charging station is configured to:
detect a voltage of the second docking terminal, and
based on identifying the flow of the current and the detected voltage being greater than or equal to a predetermined voltage, control the first switching device such that the second power is supplied to the first docking terminal.

4. The cleaner charging system of claim 3,
wherein the charging station further comprises:
a docking detection device configured to be connected to the second docking terminal and identify the flow of the current, and
wherein the charging station is further configured to:
identify the flow of the current based on information provided by the docking detection device.

5. The cleaner charging system of claim 4,
wherein the charging station further comprises:
a second switch of which one end is connected to the second docking terminal, and
a resistance of which one end is connected to the other end of the second switch, and of which the other end is grounded,
wherein the charging station is further configured to:
based on identifying that the robot cleaner was docked with the charging station, turn on the second switch, and
wherein the resistance has a smaller resistance value than a resistance of the docking detection device.

6. The cleaner charging system of claim 5, wherein the charging station is further configured to:
identify a current value of the flow of the current based on a voltage applied to the resistance, and
based on the current value being changed by greater than or equal to a predetermined ratio, control the first switching device and turn off the second switch such that the first power is supplied to the first docking terminal.

7. The cleaner charging system of claim 6,
wherein the second switching device comprises:
a third switch connecting the third docking terminal and the battery, wherein the robot cleaner is configured to:
based on identifying the flow of the current, connect the third docking terminal and the battery by turning on the third switch, and
based on charging of the battery being completed, release the connection between the first docking terminal and the battery by turning off the third switch, and
wherein the charging station is further configured to:
based on the current value being changed by greater than or equal to the predetermined ratio as the connection between the third docking terminal and the battery is released, control the first switching device and turn off the second switch such that the first power is supplied to the first docking terminal.

8. The cleaner charging system of claim 6, wherein the charging station is further configured to:
based on the current value being changed by greater than or equal to the predetermined ratio as the robot cleaner contacts the charging station in a poor contact state based on at least one of change of a posture or movement of a location of the robot cleaner, control the first switching device and turn off the second switch such that the first power is supplied to the first docking terminal.

9. The cleaner charging system of claim 4,
wherein the docking detection device comprises:
a first resistance of which one end is connected to the second docking terminal,
a second resistance of which one end is connected to the other end of the first resistance, and of which the other end is grounded, and
a transistor of which a base is connected to the other end of the first resistance, and of which an emitter is grounded,
wherein the transistor is configured to be turned on based on the flow of the current, and
wherein the charging station is further configured to:
identify that the robot cleaner was docked with the charging station based on a voltage of a collector of the transistor.

10. The cleaner charging system of claim 1, wherein the charging station is further configured to:
detect a voltage of the second docking terminal,
based on identifying the flow of the current and the detected voltage being smaller than a predetermined voltage, identify that the robot cleaner contacted in a poor contact state, and
provide information guiding poor contact to the robot cleaner or a user terminal.

11. A charging station configured to supply power to a robot cleaner, the charging station comprising:
a first docking terminal;
a second docking terminal;
a power supply device configured to generate first power having a first voltage and second power having a second voltage bigger than the first voltage;
a first switching device configured to supply the first power or the second power to the first docking terminal;
memory, comprising one or more storage media, storing instructions; and
at least one processor communicatively coupled to the power supply device, the first switching device, and the memory,
wherein the instructions, when executed by the at least one processor individually or collectively, cause the charging station to:
control the first switching device such that the first power is supplied to the first docking terminal, based on identifying a flow of a current from the first docking terminal to the second docking terminal,
identify that the robot cleaner was docked with the charging station, and
control the first switching device such that the second power is supplied to the first docking terminal.

12. The charging station of claim 11,
wherein the first switching device comprises:
a diode of which an anode is connected to a terminal outputting the second power at the power supply device, and of which a cathode is connected to the first docking terminal, and
a first switch of which one end is connected to the terminal outputting the second power at the power supply device, and of which the other end is connected to the first docking terminal, and
wherein the instructions, when executed by the at least one processor individually or collectively, further cause the charging station to:
based on identifying that the robot cleaner was docked with the charging station, turn on the first switch such that the second power is supplied to the first docking terminal.

13. The charging station of claim 11, wherein the instructions, when executed by the at least one processor individually or collectively, further cause the charging station to:
detect a voltage of the second docking terminal, and
based on identifying the flow of the current and the detected voltage being greater than or equal to a predetermined voltage, control the first switching device such that the second power is supplied to the first docking terminal.

14. The charging station of claim 13, further comprising:
a docking detection device configured to be connected to the second docking terminal and identify the flow of the current,
wherein the instructions, when executed by the at least one processor individually or collectively, further cause the charging station to:
identify the flow of the current based on information provided by the docking detection device.

15. The charging station of claim 14, further comprising:
a second switch of which one end is connected to the second docking terminal; and
a resistance of which one end is connected to the other end of the second switch, and of which the other end is grounded,
wherein the instructions, when executed by the at least one processor individually or collectively, further cause the charging station to:
based on identifying that the robot cleaner was docked with the charging station, turn on the second switch, and
wherein the resistance has a smaller resistance value than a resistance of the docking detection device.

16. The cleaner charging system of claim 15, wherein the charging station is further configured to:
identify a current value of the flow of the current based on a voltage applied to the resistance, and
based on the current value being changed by greater than or equal to a predetermined ratio, control the first switching device and turn off the second switch such that the first power is supplied to the first docking terminal.

17. The cleaner charging system of claim 16,
wherein the second switching device comprises:
a third switch connecting the third docking terminal and a battery, wherein the robot cleaner is configured to:
based on identifying the flow of the current, connect the third docking terminal and the battery by turning on the third switch, and
based on charging of the battery being completed, release the connection between the first docking terminal and the battery by turning off the third switch, and
wherein the charging station is further configured to:
based on the current value being changed by greater than or equal to the predetermined ratio as the connection between the third docking terminal and the battery is released, control the first switching device and turn off the second switch such that the first power is supplied to the first docking terminal.

18. The cleaner charging system of claim 16, wherein the charging station is further configured to:
based on the current value being changed by greater than or equal to the predetermined ratio as the robot cleaner contacts the charging station in a poor contact state based on at least one of change of a posture or movement of a location of the robot cleaner, control the first switching device and turn off the second switch such that the first power is supplied to the first docking terminal.

19. The cleaner charging system of claim 14,
wherein the docking detection device comprises:
a first resistance of which one end is connected to the second docking terminal,
a second resistance of which one end is connected to the other end of the first resistance, and of which the other end is grounded, and
a transistor of which a base is connected to the other end of the first resistance, and of which an emitter is grounded,
wherein the transistor is configured to be turned on based on the flow of the current, and
wherein the charging station is further configured to:
identify that the robot cleaner was docked with the charging station based on a voltage of a collector of the transistor.

20. The cleaner charging system of claim 11, wherein the charging station is further configured to:
detect a voltage of the second docking terminal,
based on identifying the flow of the current and the detected voltage being smaller than a predetermined voltage, identify that the robot cleaner contacted in a poor contact state, and
provide information guiding poor contact to the robot cleaner or a user terminal.
